(19) United States
(12) Patent Application Publication
(10) Pub. No.: US 2007/0113777 A1
(43) Pub. Date: May 24, 2007

(54) CaF2 single crystals with increased laser resistance, method for their preparation and use thereof

(76) Inventors: Gordon Von Der Goenna, Jena (DE); Lutz Parthier, Kleinmachnow (DE); Gunther Wehrhan, Jena (DE); Martin Letz, Mainz (DE)

Correspondence Address: STRIKER, STRIKER & STENBY, 103 EAST NECK ROAD, HUNTINGTON, NY, 11743, US

(21) Appl. No.: 11/518,368

(22) Filed: Sep. 7, 2006

(30) Foreign Application Priority Data
Sep. 19, 2005 (DE) 10 2005 044 697.3

(51) Int. Cl. C30B 13/00; C30B 29/12; C30B 21/04

(52) U.S. Cl. 117/50; 117/940

(57) ABSTRACT

A calcium fluoride single crystal with increased radiation resistance can be prepared by growing under controlled conditions of solidification from a melt of a crystal raw material containing a dopant affording ions of Al and/or Ga and/or In and/or Tl. Such a single crystal after irra-diation with at least 5×10⁸ laser pulses having a pulse energy of at least 10 mJ/cm² shows at a wavelength of 193 nm an absorption of less than 0.1%/cm.

The invention relates to the preparation of unusually radiation-resistant calcium fluoride single crystals, particularly of single crystals that have a large volume, to the crystals obtained by such a method and to the use thereof.

To produce electronic computer and control units, many circuits are arranged in a space that is steadily becoming narrower and narrower. Such miniaturized arrangements, also known as integrated circuits (IC) or chips, are produced by microlithography. This involves illuminating a light-sensitive coating, known as a photoresist and applied to a wafer, by means of a costly optical system. The demand for ever decreasing structures therefore requires illumination with ever shorter wavelengths. The illumination wavelengths currently used in microlithography are in the UV range and especially in the deep UV range (DUV). As a rule, laser light, usually from an excimer laser, is employed for this purpose, for example a KrF laser with a wavelength of 248 nm, an ArF laser with a wavelength of 193 nm and an F₂ laser with a wavelength of 157 nm. Because normal glass shows poor transmission in this UV range, special materials must be used for the optical systems in lithography or also for the corresponding laser devices. A preferred material is high-purity single-crystal calcium fluoride (fluorspar, fluorite) the transmission of which is sufficiently high even deep down in the UV range.

It is known that during the irradiation of crystals color centers are generated on defects in the crystal lattice, particularly on those created by foreign atoms. The more light or energy-rich electromagnetic waves are irradiated into a crystal, the greater is also the quantity of the color centers thus created and the greater is the light absorption in the crystal, namely the more the light transmission is reduced. The creation of such color centers and the reduction in radiation transmission associated therewith presents a problem particularly in optical components through which large amounts of energy-rich light, for example laser light, is conducted. In the case of illumination devices, in particular, for example in steppers for the production of integrated circuits, this reduces the service life thus increasing the cost. In addition, a higher absorption also leads to conversion of the radiation energy into heat which ends up in the crystal. As a result, the crystal heats up causing a change in light diffraction. Moreover, the heat-up leads to expansion and a change in lens dimensions which results in a deterioration of the imaging accuracy.

Because lithographic systems are currently being designed for a service life of at least 10 years, the optical material of which illumination and projection optical systems are made may show only minor degradation. The requirement for an increased throughput of wafers per unit time makes it necessary to develop ever more efficient lasers which in turn leads to an increased energy load on the optical materials. This is particularly true for optical elements used in excimer lasers and in radiation-conducting systems. Making available optical materials for the afore-said purposes, particularly for lasers, radiation-conducting systems and illumination optical systems showing increased resistance to radiation-induced damage, is therefore steadily gaining in importance.

It is known that the afore-described defects leading to radiation-induced damage are caused by foreign ions, particularly by cationic impurities, which are embedded in the crystal lattice in place of calcium. Polyvalent transition metals, the rare earth elements and the alkali metal elements are particularly problematical in this respect. Hence, numerous attempts have already been made to prepare crystals of higher purity.

It is disclosed in WO 03/07 1313 A1 that solarization of calcium fluoride materials arising upon irradiation in the UV range is caused by so-called non-bridge-forming fluoride atoms in the crystal lattice. According to this document, such non-bridge-forming fluorine atoms or fluorine atoms that occupy interstitial positions are caused by defects and impurities in the crystal lattice. It is assumed that the prevention or elimination of such non-bridge-forming fluorine atoms increases the resistance of the material to solarization damage. To avoid such defects, it is proposed in WO 03/07 1313 to reduce the predominant lanthanide and transition metal impurities by addition of a monovalent dopant. Mentioned as dopants are metals from the group consisting of lithium (Li), sodium (Na), potassium (K), rubidium (Rb), cesium (Ce), thallium (Th), copper (Cu), silver (Ag) and gold (Au). The dopant, particularly sodium and potassium, is to be used in excess over the impurities. Although such a material shows sufficient power characteristics for irradiation with a CW laser having a 40 W/cm² energy output at fluence levels of 20-100 MW per cm², it is, however, not sufficiently stable for currently required energy densities in which case even a single laser pulse creates in the material energies of several kW/cm², energies which have to be conducted through the crystal.

Hence, attempts have already been made to reduce the particularly troublesome sodium and/or potassium content in the CaF₂ crystal.

For example, EP 0 875 778 describes an optical imaging system for UV lasers with a wavelength below 300 nm the optical elements of which consist of a calcium fluoride crystal and show a sodium concentration of less than 0.2 ppm and preferably less than 0.01 ppm.

In EP 0 987 538 is described an optical system for lithography equipment for wavelengths below 200 nm, the optical elements of which consist of calcium fluoride and have a potassium content of less than 0.5 ppm. Such optical elements are said to have a higher resistance to transmission degradation.

Marathon tests under loads prevailing in lithography, namely of more than 10⁹ pulses with 10 to 20 mJ/cm², have shown that even a material containing as low an amount of alkali metal contamination as previously indicated can still be appreciably degraded. An absolute purification of the crystal raw material to remove the alkali metals, for example by vaporization or segregation, however, has limits set by thermodynamic laws. Purification to concentrations of a few tens of ppb of sodium or potassium therefore cannot be achieved or can be achieved only with difficulty. It has been found, however, that upon irradiation over prolonged time periods even such a concentration can produce degradation phenomena in calcium fluoride as indicated by a decrease in transmission at the operating wavelength, particularly at 193 nm.

In view of this, the object of the invention is to provide a calcium fluoride material for laser materials which shows high radiation resistance even upon prolonged service and when used with high energies, namely with energy-rich laser pulses, for which the high energy for irradiation is not distributed over a prolonged time period, but exposes the material at the same time within a fraction of a second.

This objective is reached by way of the features defined in the claims.

In fact, we have found that an optical element with unusually high radiation resistance can be produced from a calcium fluoride single crystal if to the base material during the crystal growing is added a salt containing as the cation Al, Ga, In and/or Tl, with Al and Ga being particularly preferred. Advantageously, the salts are fluorides. This solution according to the invention is even more surprising considering that we have found that the disturbing alkali metal elements such as sodium and potassium accumulate in the melt and at the end of the crystal growing are therefore incorporated into the crystal lattice in increasing concentration.

We have, in fact, found that the addition according to the invention not only brings about an improvement in the distribution of the undesirable alkali metal elements in the crystal, but also causes these elements to lose their troublesome solarizing action. We have also found, according to the invention, that a particular dopant should be added in an amount ar least equal to the molar quantity of the unwanted alkali metal ions and preferably should exceed this amount. Advantageously, the amount of dopant added should be at least twice the molar quantity, with at least three times the molar quantity being particularly preferred. Typically the upper limit for the doping according to the invention is at the most a ten-fold, particularly a six-fold and especially a five-fold molar excess.

As a result of the addition of an excess of dopant, at the end of the crystal-growing process the amount of trivalent doping elements present in the crystal is approximately the same as the amount of the troublesome monovalent alkali metal elements.

Only the actual process conditions and the different distribution coefficients are the reason why an excess of dopant must be added.

Typical crystal materials, in particular those used as raw materials, contain alkali metal impurities amounting to at the most 2 ppm and particularly at the most 0.5 ppm. Typically, the finished grown crystals have an alkali metal content and especially a sodium and/or potassium content of at the most 30 ppb and 0.03 ppb, respectively. Unless otherwise indicated, all these data mean ppm by weight (ppmw). That by the method of the invention the radiation resistance and particularly the laser resistance of these calcium fluoride crystals can be increased in this manner is even more surprising considering that according to the prior art the negative effects of the rare earths is even increased by an excess of monovalent alkali metal ions and/or alkaline earth metal ions.

The invention also relates to crystals obtained by the method of the invention. Such crystals show a resistance to laser radiation with an energy per pulse of at least 2 MW/cm² and particularly at least 5 MW/cm².

Thus, the crystals readily withstand laser radiation with an energy of at least 40 MW/cm² (4,000 Hz×10 mJ/cm² per s typically corresponding to the load in an illumination system) and preferably at least 150 W/cm² (6,000 Hz×25 mJ/cm² per s), with at least 600 W/cm² (6,000 Hz×100 mJ/cm² per s) being particularly preferred. In a particularly preferred embodiment, the crystals of the invention readily withstand up to 900 W/cm² (6,000 Hz×150 mJ/cm² per s) and more.

The service life of the crystals of the invention under the indicated conditions of energy density per pulse or of the energy load in W/cm² for the indicated application cases as optical components directly built into the laser or as radiation-generating systems amounts close to the exit from the laser to more than 0.5 billion pulses, particularly more than 2 billion pulses and particularly more than 5 billion pulses.

In an illumination system or projection system, the crystals of the invention reach a service life of more than 10 billion pulses at energy densities of up to 30 mJ/cm² per pulse.

The crystals of the invention contain alkali metal impurities in an amount of preferably at the most 0.1 ppm and particularly at the most 0.05 ppm, amounts of at the most 0.001 ppm or 10 ppb being particularly preferred. Especially preferred are crystals containing at the most 5 ppb and particularly at the most 2 ppb of alkali metals. These amounts are preferably based on the maximum content of sodium and/or potassium.

The crystals of the invention were prepared by use of a dopant which advantageously was selected from among AlF₃, GaF₃, InF₃ and/or TlF₃, with AlF₃ and GaF₃ being particularly preferred. Doping with AlF₃ is especially preferred. The dopant is to be added in at least the molar amount at which it is present in the finished crystal obtained by growing by a standard process without doping. Usually, however, an excess of the dopant is added. Preferably, however, the crystals of the invention contain at least twice the amount of dopant, a minimum amount of dopant of three times relative to the troublesome alkali metal ions being particularly preferred. The maximum amounts of dopant are advantageously a ten-fold of the molar amount of alkali metal, a maximum amount of six times and particularly five times the said molar amount being especially preferred.

Even after all color centers have been formed, a crystal of the invention at 193 nm still shows a light transmission of at least 10% of the original value, a transmission value of at least 12% and particularly at least 13% being common. After the formation of all color centers, the preferred crystals still show a residual transmission of 14% and particularly at least 15% of the original light transmission at a wavelength of 193 nm.

The formation of all color centers can readily be attained with the aid of an exposure to x-ray irradiation. Such x-ray irradiation is described, for example, in DE 100 50 349 A1. Another possible method, for example, consists of irradiation with a cobalt source at 1 megarad doses. It is known for these two methods that they correlate well with a long-term load of an excimer laser and that thereby the final condition of the formation of color centers can be reached in a short time, something that with laser radiation can be accomplished only after prolonged exposure.

The crystals of the invention preferably are large-volume crystals having a diameter of at least 50 mm and particularly at least 80 mm, common crystals of the invention showing a minimum diameter of 10 mm. Particularly preferred crystals have a diameter of at least 150 mm and particularly at least 200 mm. Usually, the crystals are at least 50 mm high, heights of at least 70 mm and particularly at least 80 mm being preferred. Advantageous crystal heights amount to at least 100 mm and particularly at least 150 mm.

In a particularly preferred embodiment of the invention, the sodium content of the crystal raw material is determined before the preparation. This is advantageously done by neutron activation analysis. Quantities of even less than 1 ppb can be determined in this manner. If the alkali metal content and particularly the sodium and/or potassium content is known, then from this material and under the same conditions and by the same method as for the subsequent crystal-growing, a test crystal is grown and studied to determine the content of the alkali metal and particularly the content of sodium and/or potassium of this crystal grown by a standard growing process. Based on this measured amount, an appropriate amount of dopant is added. Preferably at least an equimolar amount of dopant is added, an excess being preferred so that on a molar basis the amount of dopant, namely of fluorides of the elements of the third main group, is greater than the amount of the troublesome alkali metal impurities. We have found that as a result of the distribution coefficients it is possible in this manner to incorporate into the final crystal alkali metal ions and aluminum ions in an approximately equimolar ratio. Typical molar ratios of alkali metal ions to dopant ions, particularly Na⁺: Al³⁺, are from 1:4 to 4:1 and particularly from 1:2 to 2:1, ratios of 1:0.8 to 1.2 and particularly from 1:0.9 to 1.1 being particularly advantageous.

The crystals of the invention are used particularly in laser technology and preferably for optical elements exposed to the full laser energy, namely for optical elements used in the laser system directly for radiation generation and/or radiation conduction. Such lenses are usually exposed to an energy of at least 20 mJ/cm² per pulse and particularly at least 50 mJ/cm² per pulse, with energy quantities of at least 100 mJ/cm² per pulse or at least 150 mJ/cm² per pulse frequently being attained. Naturally, the crystals of the invention are also well suited for optical elements used, for example, in optical systems for illumination or irradiation, for example in photolithography. Such elements are exposed to energy densities of only about 10-20 mJ/cm². The frequency of the lasers operating at the said energy densities amounts to up to 4,000 Hz, preferably up to 6,000 Hz and particularly up to 8,000 Hz and higher.

The following examples will describe the invention in greater detail.

Preparation of the Calcium Fluoride Single Crystals.

In each case, 200 mg of PbF₂ was added as scavenger to a quantity of 500 g of CaF₂ to remove oxygen impurities followed by the addition of appropriate amounts in mol/ppm of sodium or potassium impurities and of the dopant. It was determined in preliminary tests that it is almost impossible to dope the crystal only with the alkali metal impurities. Because of the relatively high vaporization rate and unequal distribution between melt and crystal, only the amounts of alkali metal added as dopant that were clearly below 1% could be determined. For this reason the alkali metal ion was added in the form of the corresponding (alkali metal)₃XF₆ ion, where X stands for an element of the third main group. In this manner, it was possible to achieve recovery rates of 20% of the originally added substance.

With the crystals obtained in this manner, an absorption spectrum was recorded before irradiation. The crystals were then subjected to x-ray irradiation as described in DE 100 50 349 to create all theoretically possible color centers. Thereafter, an absorption spectrum was recorded over the same wavelength region as before and the difference between the two spectra was plotted. The difference spectra are shown, for example, in the following figures, where

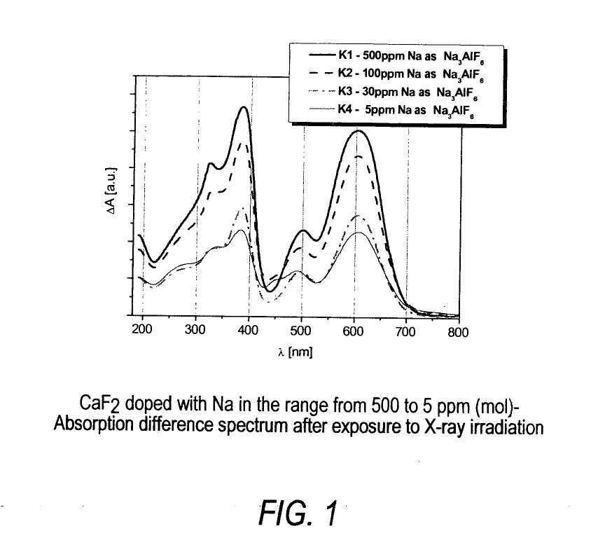

FIG. 1 is an absorption spectrum [sic] for crystals containing in the CaF₂ different amounts of added sodium ions, said amounts varying in the range of 500 to 5 ppm/mol;

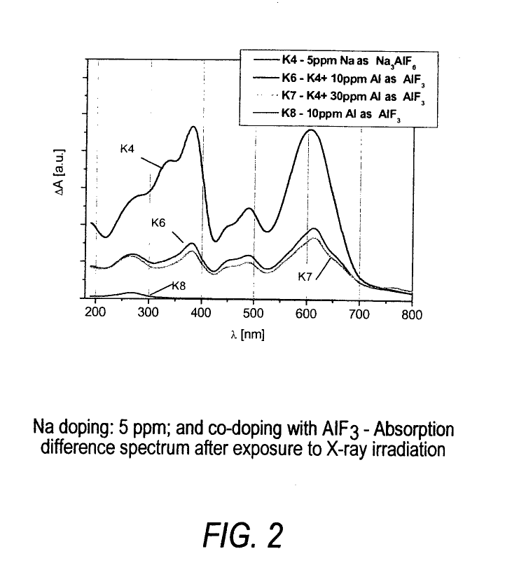

FIG. 2 is an absorption difference spectrum for a crystal to which sodium has been added and which has been doped with AlF₃, and

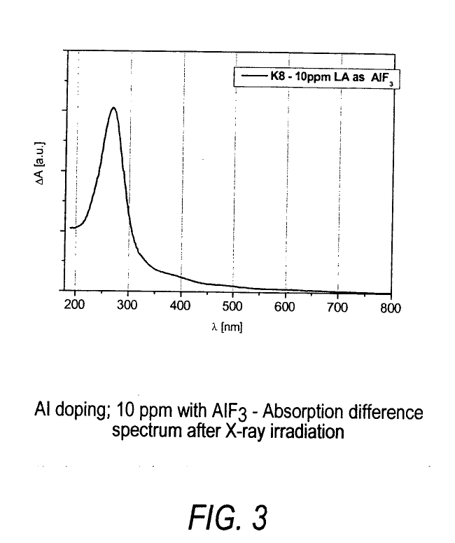

FIG. 3 is an absorption difference spectrum for pure CaF₂ and for an AlF₃-doped crystal without sodium.

As can be seen particularly from FIG. 1, an increase in sodium concentration in the crystal resulted in a marked increase in laser damage in the material as indicated by the formation of typical color centers, particularly of the F-center (380 nm) and the M-center (600 nm). Moreover, this difference spectrum also shows an appreciable increase in absorption at the particularly important operating wavelength of 193 nm, an increase that corresponds to the increase in sodium present in the crystal.

FIG. 2 shows the decrease in the color centers at 380 and 600 nm induced by x-ray irradiation. In particular, the simultaneous decrease in absorption modification at 193 nm can also be seen. The formation of a shoulder or of a minor peak at about 270 nm is due to the added AlF₃. In spite of this newly appearing absorption band, the difference spectra show clearly that in a crystal containing 5 ppm of sodium in the form of cryolite the addition of 10 ppm of pure AlF₃ or of 30 ppm of pure AlF₃, even when all theoretically possible color centers have been formed, brings about an increase in transmission at 193 nm namely the light transmission is increased to about 14-15%. This is particularly noteworthy considering that with the same sodium content (in the form of cryolite) the transmission of the crystal shows only 1% of its original value, indicating practically a full loss of light transmission or a UV-blocking material. Optically, after the formation of all color centers such a crystal which is not protected with AlF₃ has a cobalt-blue color.

The invention also relates to the use of the crystals prepared by the method of the invention for the production of lenses, prisms, light-conducting rods, optical windows and optical components for DUV photolithography, steppers, lasers, particularly excimer lasers, computer chips as well as integrated circuits and electronic devices containing such circuits and chips, furthermore laser optical systems for exposure to radiation having an energy of at least 50 mJ/cm² per pulse, preferably at least 100 mJ/cm² per pulse and particularly 150 mJ/cm² per pulse as well as optical systems and lenses for radiation generation and radiation conduction after the laser beam has left the laser.

1. Method for preparing calcium fluoride single crystals with increased radiation re-sistance by growing a crystal under controlled conditions of solidification of a melt made of crystal raw material containing a dopant, characterized in that the CaF₂ melt contains as the dopant ions of Al and/or Ga and/or In and/or Tl.

2. Method as defined in claim 1, characterized in that the melt contains alkali metal ions in an amount of up to 1 ppmw.

3. Method as defined in claim 1, characterized in that the alkali metal ions are Na⁺ and/or K⁺.

4. Method as defined in claim 1, characterized in that the melt contains a molar excess of dopant, based on the alkali metal ions.

5. Method as defined in claim 1, characterized in that the content of alkali metal ions of a crystal specimen obtained by carrying out a standard growing pro-cess without doping is determined and that, based on this content, at least a double molar amount of dopant is added to the melt or to the starting material.

6. Calcium fluoride single crystal with a diameter of at least 50 mm and a height of at least 50 mm containing up to 1 ppmw of an alkali metal contaminant, characterized in that it contains as the dopant AlF₃, GaF₃, InF₃ and/or TlF₃.

7. Calcium fluoride single crystal as defined in claim 6, characterized in that after irradiation with at least 5×10⁸ laser pulses having a pulse energy of at least 10 mJ/cm² it shows at a wavelength of 193 nm an absorption of less than 0.1%/cm.

8. Use of a crystal obtained by the method defined in claim 1 or of a crystal obtained as defined in claim 6 for producing lenses, prisms, light-conducting rods, optical windows and optical components for DUV photolithography, steppers, lasers, especially excimer lasers, computer chips and integrated circuits and electronic devices containing such circuits and chips, or a laser optical system for transmission of an energy density of at least 50 mJ/cm² per pulse.
